(19) United States
(12) Patent Application Publication
(10) Pub. No.: US 2017/0162095 A1
(43) Pub. Date: Jun. 8, 2017

(54) SHIFT REGISTER UNIT, GATE DRIVING CIRCUIT AND DISPLAY DEVICE

(71) Applicant: BOE Technology Group Co., Ltd., Beijing (CN)

(72) Inventors: Chen Song, Beijing (CN); Zhongyuan Wu, Beijing (CN); Hongjun Xie, Beijing (CN); Kun Cao, Beijing (CN)

(73) Assignee: BOE Technology Group Co., Ltd., Beijing (CN)

(21) Appl. No.: 15/322,543

(22) PCT Filed: Apr. 8, 2016
(86) PCT No.: PCT/CN2016/078825

§ 371 Date: Dec. 28, 2016

(30) Foreign Application Priority Data
Jun. 3, 2015 (CN) 201510300522.8

(51) Int. Cl. G09G 3/20; G11C 19/28

(52) U.S. Cl. CPC G09G 3/20; G11C 19/28; G09G 2310/0286; G09G 2310/08

(57) ABSTRACT

Embodiments of the present disclosure provide a shift register unit, a gate driving circuit and a display device. The shift register unit comprises two reset-set RS flip-flops. An set S terminal of a first RS flip-flop receives a trigger signal, and a reset R terminal of the first RS flip-flop receives a clock signal. An S terminal of a second RS terminal receives the clock signal, a R terminal of the second RS flip-flop is connected to a Q terminal of the first RS flip-flop, and a Q terminal of the second RS flip-flop is an output terminal of the shift register unit.

### FIELD

The present disclosure relates to the field of display technology, and particularly to a shift register unit, a gate driving circuit and a display device

### BACKGROUND

Gate drive on array (GOA) technology is a technology that replaces a driving circuit made of an external silicon wafer by directly fabricating a gate driving circuit on an array substrate. The technology can be directly achieved around a display panel, thereby reducing the manufacturing procedures, reducing the cost of product and improving the integration level of the display panel.

In a display panel based on the GOA technology, a pixel circuit that drives each pixel usually needs some external signals to control the display of the pixel. A commonly used pixel circuit shown in FIG. 1 comprises three transistors (transistor T1, transistor T2 and transistor T3), two capacitors (capacitor C1 and capacitor C2) and a light emitting diode D. A switch signal S1 controls turn-on or turn-off of the transistor T2 and a switch signal S2 controls turn-on or turn-off of the transistor T3. A data signal DATA is stored in the capacitor C1 when the transistor T2 is turned on. A power supply signal ELVDD and a power supply signal ELVSS form a voltage difference across the light emitting diode D.

The pixel circuit shown in FIG. 1 is required to receive the switch signal S1 and the switch signal S2 outputted from the GOA circuit and receive the data signal DATA on a data line. The switch signal Si required by respective pixel circuits that drive the n-th row of pixels needs to be advanced by a specific length of time with respect to the switch signal Si required by respective pixel circuits that drive the (n+1)-th row of pixels. Similarly, the switch signal S2 required by respective pixel circuits that drive the n-th row of pixels needs to be advanced by a specific length of time with respect to the switch signal S2 required by respective pixel circuits that drive the (n+1)-th row of pixels. That is, the switch signal outputted from the GOA circuit to the pixel circuits of the subsequent row can be obtained by shifting the switch signal outputted from the GOA circuit to the pixel circuits of the previous row.

However, the commonly used circuits such as shift register, which generate shift signals between rows of the array substrate, are usually complicated in structure. To manufacture such a circuit around the display panel would complicate the manufacturing process of the display panel and increase the cost of the display panel.

### SUMMARY

Embodiments of the present disclosure disclose a shift register unit, a gate driving circuit and a display device, which may at least alleviate or eliminate one or more of the above problems in the prior art.

A shift register unit provided by embodiments of the present disclosure comprises two reset-set RS flip-flop. A set S terminal of a first RS flip-flop receives a trigger signal, and a reset R terminal of the first RS flip-flop receives a clock signal. An S terminal of a second RS flip-flop receives the clock signal, and an R terminal of the second RS flip-flop is connected to a Q terminal of the first RS flip-flop.

A gate driving circuit provided by embodiments of the present disclosure comprises a plurality of shift register units provided by embodiments of the present disclosure. A trigger signal received by an S terminal of a first RS flip-flop in the (n+1)-th shift register unit is a signal outputted from a Q terminal of a second RS flip-flop in the n-th shift register unit, n being a positive integer. When n is an odd number, a clock signal received by the n-th shift register unit is a first clock signal; when n is an even number, a clock signal received by the n-th shift register unit is a second clock signal. A frequency of the first clock signal is equal to a frequency of the second clock signal.

A display device provided by embodiments of the present disclosure comprises the gate driving circuit provided by embodiments of the present disclosure.

The shift register unit provided by embodiments of the present disclosure consists of reset-set (RS) flip-flop. The signal outputted by a shift register unit is a signal obtained by shifting the trigger signal received by the shift register unit by half a cycle of the clock signal. Therefore, the signal outputted by the shift register unit provided by embodiments of the present disclosure can serve as a switch signal required by the pixel circuits in the display panel. Moreover, since the shift register unit provided by embodiments of the present disclosure only consists of RS flip-flops, the circuit is simple in structure, which simplifies the manufacturing procedure of the display panel comprising this circuit.

### BRIEF DESCRIPTION OF DRAWINGS

FIG. 1 is a structural schematic view of a pixel circuit in the prior art;

FIG. 2 is a structural schematic view of a shift register unit provided by embodiments of the present disclosure;

FIG. 3 is a structural schematic view of a gate driving circuit provided by embodiments of the present disclosure;

FIG. 4 is a schematic view illustrating the signals of the Q terminals of respective RS flip-flops in the gate driving circuit provided by embodiments of the present disclosure;

FIG. 5 is a schematic view showing a structure of respective RS flip-flops in the shift register unit or the gate driving circuit provided by embodiments of the present disclosure;

FIG. 6 is a schematic view showing a structure of NOR gates in respective RS flip-flops in the shift register unit or the gate driving circuit provided by embodiments of the present disclosure;

FIG. 7 is a schematic view showing another structure of NOR gates in respective RS flip-flops in the shift register unit or the gate driving circuit provided by embodiments of the present disclosure; and

FIG. 8 is a schematic view showing yet another structure of NOR gates in respective RS flip-flops in the shift register unit or the gate driving circuit provided by embodiments of the present disclosure.

### DETAILED DESCRIPTION

The shift register unit provided by embodiments of the present disclosure only consists of RS flip-flops. The signal outputted by a shift register unit can serve as a switch signal required by a row of pixel circuits in the display panel. Moreover, the circuit is simple in structure, which simplifies the manufacturing procedure of the display panel comprising this circuit.

Specific implementations of the shift register unit, the gate driving circuit and the display device provided by embodiments of the present disclosure are described below with reference to the drawings.

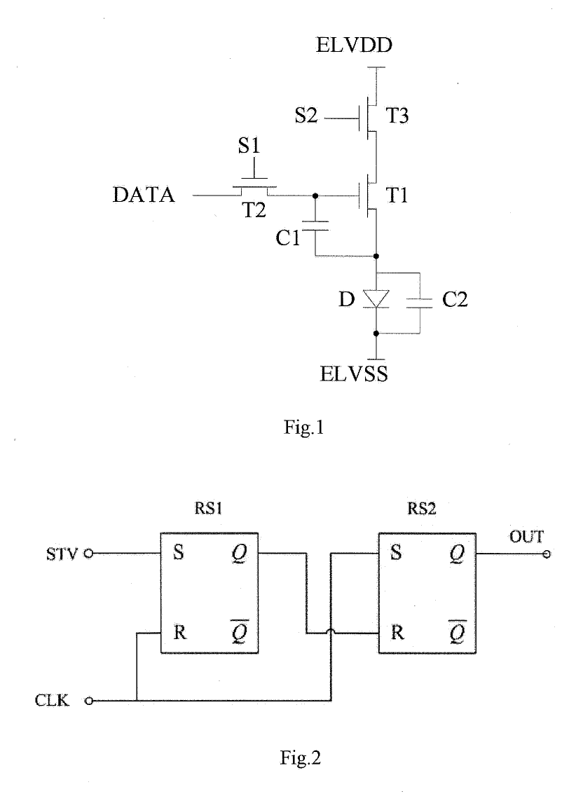

A shift register unit provided by embodiments of the present disclosure comprises, as shown in FIG. 2, two RS flip-flops. A set (S) terminal of a first RS flip-flop RS1 receives a trigger signal, and a reset R terminal of the first RS flip-flop RS1 receives a clock signal CLK. An S terminal of a second RS flip-flop RS2 receives the clock signal CLK, and an R terminal of the second RS flip-flop RS2 is connected to a Q terminal of the first RS flip-flop RS1.

A Q terminal of the second RS flip-flop RS2 in a shift register unit is an output terminal OUT of the shift register unit.

When the shift register unit provided by embodiments of the present disclosure is the first shift register unit in the gate driving circuit, the trigger signal received by the S terminal of the first RS flip-flop in the shift register unit provided by embodiments of the present disclosure is a frame start signal STV. When the shift register unit provided by embodiments of the present disclosure is any shift register unit other than the first shift register unit in the gate driving circuit, the trigger signal received by the S terminal of the first RS flip-flop in the shift register unit provided by embodiments of the present disclosure is a signal outputted from an output terminal of a previous-stage shift register unit. FIG. 2 only illustrates the situation that the shift register unit is the first shift register unit in the gate driving circuit.

For an active-low RS flip-flop, when the R terminal is at high level, regardless of whether the S terminal is at high level or at low level, the Q terminal is at low level and the U terminal is at high level. When the R terminal is at low level and the S terminal is at high level, the Q terminal is at low level and the Q̅ terminal is at high level. When the R terminal is at low level and the S terminal is at low level, the Q terminal is at high level and the Q̅ terminal is at low level. When the R terminal is at low level and the level of the S terminal changes from high level to low level for the first time, the level of the Q terminal changes from low level to high level, and the level of the Q̅ terminal changes from high level to low level accordingly. When the R terminal is at low level and the level of the S terminal changes from low level to high level, the levels of the Q terminal and the Q̅ terminal are both unchanged. This is the most basic logic of an RS flip-flop. In practice, if other logic combinations are to be achieved, it is only required to add an inverter at the input terminals (i.e. R terminal and S terminal) of the RS flip-flop.

The RS flip-flop in the shift register unit provided by embodiments of the present disclosure may be an RS flip-flop having no inverter at the input terminals (i.e. R terminal and S terminal), and also be an RS flip-flop having inverters at the input terminals.

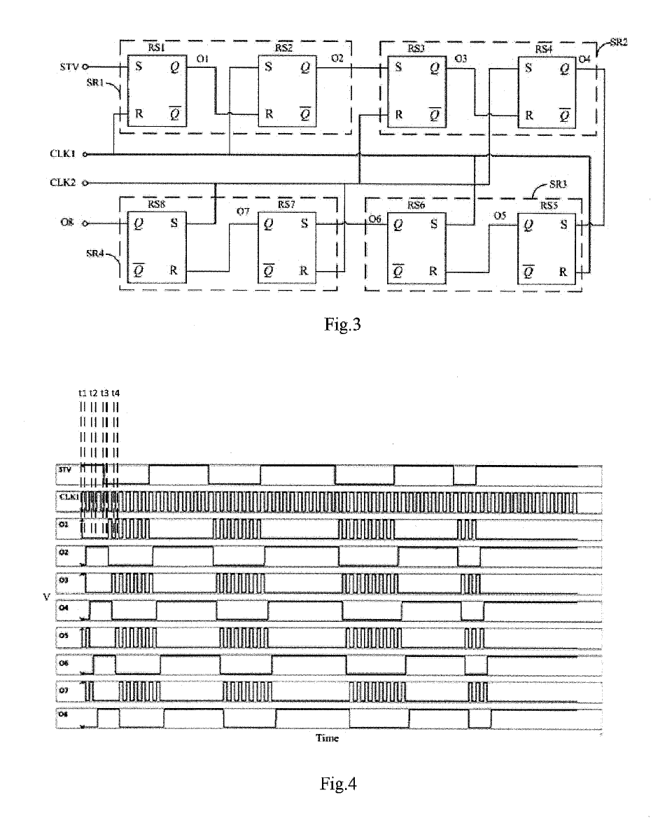

A gate driving circuit provided by embodiments of the present disclosure comprises, as shown in FIG. 3, a plurality of shift register units provided by embodiments of the present disclosure. A trigger signal received by an S terminal of a first RS flip-flop in the (n+1)-th shift register unit is a signal outputted from a Q terminal of a second RS flip-flop in the n-th shift register unit, n being a positive integer. When n is an odd number, a clock signal received by the n-th shift register unit is a first clock signal CLK1. When n is an even number, a clock signal received by the n-th shift register unit is a second clock signal CLK2. A frequency of the first clock signal is equal to a frequency of the second clock signal.

The signal outputted from the Q terminal of the second RS flip-flop in each shift register unit in the gate driving circuit is a gate driving signal outputted by the gate driving circuit to respective rows of pixels in the display panel.

FIG. 3 only illustrates the situation that the gate driving circuit comprises four shift register units, i.e. SR1, SR2, SR3 and SR4. That is, the gate driving circuit in FIG. 3 comprises eight RS flip-flops. Certainly, the number of flip-flops included in the circuit should be twice the number of rows of pixels in the display panel.

Optionally, the first clock signal CLK1 and the second clock signal CLK2 received by the gate driving circuit provided by embodiments of the present disclosure are complementary to each other. That is, when the first clock signal CLK1 is at low level, the second clock signal CLK2 is at high level; when the first clock signal CLK1 is at high level, the second clock signal CLK2 is at low level.

When the first clock signal CLK1 is complementary to the second clock signal CLK2, signals of the Q terminals of respective RS flip-flops in the gate driving circuit shown in FIG. 3 are shown in FIG. 4 in which the horizontal axis represents a time axis Time and the vertical axis represents voltage V.

In FIG. 4, the signal O1 is a signal of the Q terminal of the first RS flip-flop, the signal O2 is a signal of the Q terminal of the second RS flip-flop, the signal O3 is a signal of the Q terminal of the third RS flip-flop, the signal O4 is a signal of the Q terminal of the fourth RS flip-flop, the signal O5 is a signal of the Q terminal of the fifth RS flip-flop, the signal O6 is a signal of the Q terminal of the sixth RS flip-flop, the signal O7 is a signal of the Q terminal of the seventh RS flip-flop, and the signal O8 is a signal of the Q terminal of the eighth RS flip-flop. The signal O2 is a signal outputted by the first shift register unit SR1, the signal O4 is a signal outputted by the second shift register unit SR2, the signal O6 is a signal outputted by the third shift register unit SR3, and the signal O8 is a signal outputted by the fourth shift register unit SR4.

In FIG. 4, the first clock signal CLK1 and the second clock signal CLK2 are both pulse signals having a duty cycle of 50%. The waveform diagram of the second clock signal CLK2 is not shown in FIG. 4. It can be seen from FIG. 4 that the signal O1, the signal O3, the signal O5 and the signal O7 are all multi-pulse signals, and the signal O2, the signal O4, the signal O6, and the signal O8 are all single-pulse signals. Moreover, the signal O2 lags behind the trigger signal STV by half a clock cycle of the first clock signal CLK1, the signal O4 lags behind the signal O2 by half a clock cycle of the first clock signal CLK1, the signal O6 lags behind the signal O4 by half a clock cycle of the first clock signal CLK1, and the signal O8 lags behind the signal O6 by half a clock cycle of the first clock signal CLK1. Moreover, for any one of the signal O2, the signal O4, the signal O6 and the signal O8, the pulse width of the pulse in the signal is controlled by the pulse width of the pulse in the trigger signal STV. For any one of the signal O1, the signal O3, the signal O5 and the signal O7, the number of pulses in the signal is controlled by the pulse width of the pulse in the trigger signal STV.

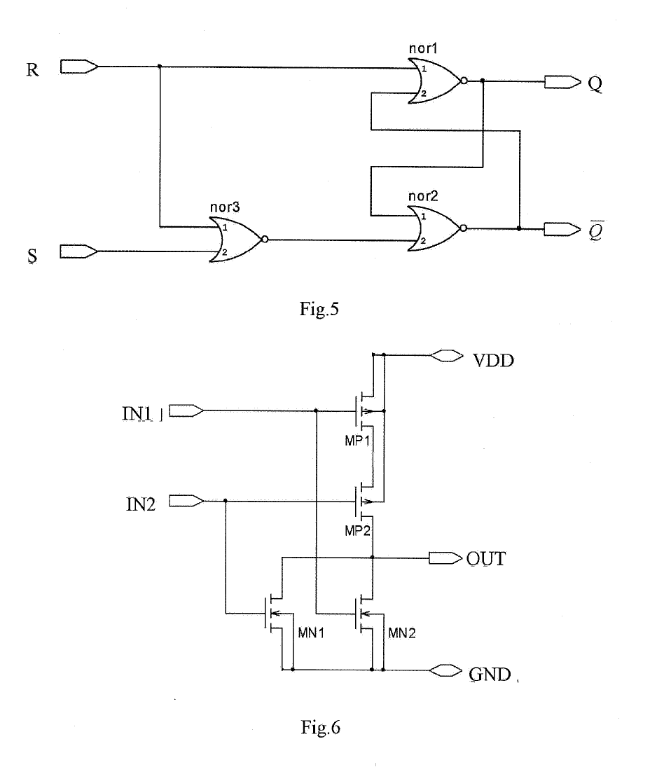

Optionally, each RS flip-flop in the shift register unit or the gate driving circuit provided by embodiments of the present disclosure comprises, as shown in FIG. 5, three NOR gates. One input terminal of a first NOR gate nor1 is an R terminal of the RS flip-flop, another input terminal of the first NOR gate norl is connected to an output terminal of a second NOR gate nor2, and an output terminal of the first NOR gate norl is a Q terminal of the RS flip-flop.

One input terminal of the second NOR gate nor2 is connected to the output terminal of the first NOR gate norl, another input terminal of the second NOR gate nor2 is connected to an output terminal of a third NOR gate nor3, and the output terminal of the second NOR gate nor2 is a U terminal of the RS flip-flop.

One input terminal of the third NOR gate nor3 is the R terminal of the RS flip-flop, and another input terminal of the third NOR gate nor3 is an S terminal of the RS flip-flop.

Table 1 below shows a truth table of the RS flip-flop shown in FIG. 5.

TABLE 1
Truth table of the RS flip-flop shown in FIG. 5

| S | R | Q |
|---|---|---|
| 0 | 1 | 0 |
| 1 | 0 | Maintain |
| 1 | 1 | 0 |
| 0 | 0 | 1 |

In light of the truth table shown in Table 1, the waveform diagrams shown in FIG. 4 and the logic of the RS flip-flop are described taking the first RS flip-flop RS1 in FIG. 3 as an example.

In the period t1, the R terminal (i.e. CLK1 terminal) of RS1 is at high level, the S terminal (i.e. STV terminal) of RS1 is at high level, and the Q terminal of RS1 is at low level.

In the period t2, the R terminal of RS1 is at low level, the S terminal of RS1 is at high level, and the Q terminal of RS1 maintains the previous state, i.e. remaining at low level.

In the period t3, the R terminal of RS1 is at high level, the S terminal of RS1 is at low level, and the Q terminal of RS1 is at low level.

In the period t4, the R terminal of RS1 is at low level, the S terminal of RS1 is at low level, and the Q terminal of RS1 is at high level.

As for other time periods and other RS flip-flops, the working process is similar to the above process.

Optionally, at least one NOR gate in the RS flip-flop comprises, as shown in FIG. 6, two p-type transistors and two n-type transistors.

A gate of a first p-type transistor MP1 is one input terminal IN1 of a NOR gate, a first terminal of the first p-type transistor MP1 receives a first voltage signal VDD, and a second terminal of the first p-type transistor MP1 is connected to a first terminal of a second p-type transistor MP2.

A gate of the second p-type transistor MP2 is another input terminal IN2 of the NOR gate, and a second terminal of the second p-type transistor MP2 is an output terminal OUT of the NOR gate.

A gate of a first n-type transistor MN1 is connected to the gate of the second p-type transistor MP2, a first terminal of the first n-type transistor MN1 is the output terminal OUT of the NOR gate, and a second terminal of the first n-type transistor MN1 receives a second voltage signal GND.

A gate of a second n-type transistor MN2 is connected to the gate of the first p-type transistor MP1, a first terminal of the second n-type transistor MN2 is the output terminal OUT of the NOR gate, and a second terminal of the second n-type transistor MN2 receives the second voltage signal GND.

A substrate of the first p-type transistor MP1 is connected to a substrate of the second p-type transistor MP2 and receives the first voltage signal VDD; a substrate of the first n-type transistor MN1 is connected to a substrate of the second n-type transistor MN2 and receives the second voltage signal GND.

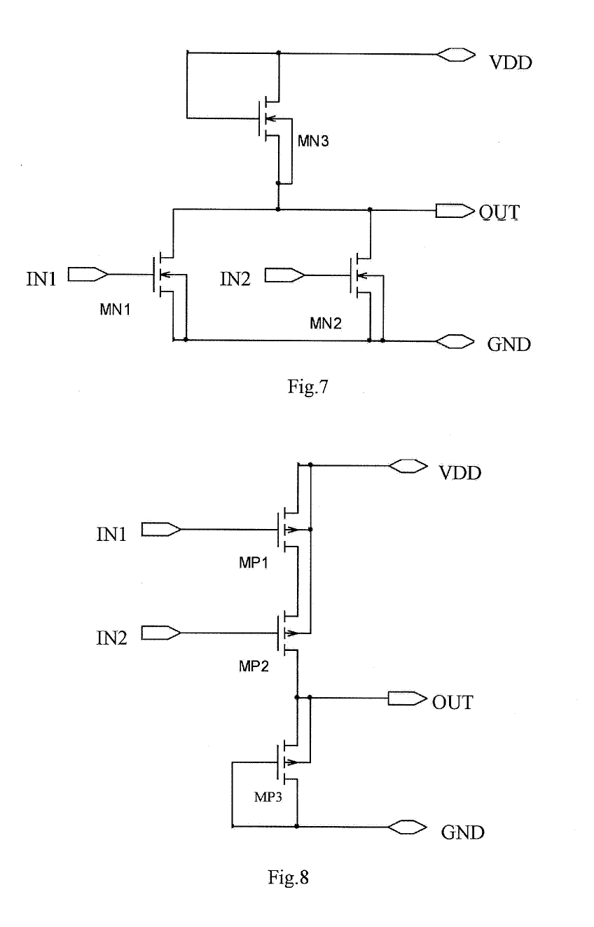

Optionally, at least one NOR gate in the RS flip-flop comprises, as shown in FIG. 7, three n-type transistors.

A gate of a first n-type transistor MN1 is one input terminal IN1 of a NOR gate, a first terminal of the first n-type transistor MN1 is an output terminal OUT of the NOR gate, and a second terminal of the first n-type transistor MN1 and a substrate of the first n-type transistor MN1 both receive a second voltage signal GND.

A gate of a second n-type transistor MN2 is another input terminal IN2 of the NOR gate, a first terminal of the second n-type transistor MN2 is the output terminal OUT of the NOR gate, and a second terminal of the second n-type transistor MN2 and a substrate of the second n-type transistor MN2 both receive the second voltage signal GND.

A gate of a third n-type transistor MN3 and a first terminal of the third n-type transistor MN3 both receive a first voltage signal VDD, a second terminal of the third n-type transistor MN3 is connected to a substrate of the third n-type transistor MN3 and is the output terminal OUT of the NOR gate.

Optionally, at least one NOR gate in the RS flip-flop comprises, as shown in FIG. 8, three p-type transistors.

A gate of a first p-type transistor MP1 is one input terminal IN1 of a NOR gate, a first terminal of the first p-type transistor MP1 receives a first voltage signal VDD, and a second terminal of the first p-type transistor MP1 is connected to a first terminal of a second p-type transistor MP2.

A gate of the second p-type transistor MP2 is another input terminal IN2 of the NOR gate, and a second terminal of the second p-type transistor MP2 is an output terminal OUT of the NOR gate.

A substrate of the first p-type transistor MP1 is connected to a substrate of the second p-type transistor MP1 and receives the first voltage signal VDD.

A gate of a third p-type transistor MP3 is connected to a first terminal of the third p-type transistor MP3 and receives a second voltage signal GND, and a second terminal of the third p-type transistor MP3 is connected to a substrate of the third p-type transistor MP3 and is the output terminal OUT of the NOR gate.

The voltage level of the first voltage signal VDD is higher than that of the second voltage signal GND.

The three NOR gates in the RS flip-flop in the shift register unit or the gate driving circuit provided by embodiments of the present disclosure may employ the same structure or different structures.

For a transistor (whether it is an n-type transistor or a p-type transistor) in the display field, there is no clear distinction between the drain and the source. Therefore, the first terminal of the transistor mentioned in embodiments of the present disclosure may be the source (or drain) of the transistor, and the second terminal of the transistor may be the drain (or source) of the transistor. If the source of the transistor is the first terminal, the drain of the transistor is the second terminal. If the drain of the transistor is the first terminal, the source of the transistor is the second terminal.

The display device provided by embodiments of the present disclosure comprises the gate driving circuit provided by embodiments of the present disclosure.

Those skilled in the art can understand that the drawings are just schematic views of exemplary embodiments, and the modules or flows in the drawings may be not necessary to implement the present disclosure.

Those skilled in the art can understand that the modules in a device in an embodiment can be distributed in the device of the embodiment as described by the embodiment, and can also be located in one or more devices different from the present embodiment based on corresponding changes. The modules in the above embodiment can be merged into one module and can also be further split into a plurality of sub modules.

Apparently, those skilled in the art can make various modifications and variations to the present disclosure without departing from the spirit and scope thereof. In this way, if these modifications and variations to the present disclosure fall within the scope of the claims of the present disclosure and equivalent technologies thereof, the present disclosure also intends to encompass these modifications and variations.

1. A shift register unit, comprising two reset-set RS flip-flops,
a set S terminal of a first RS flip-flop receiving a trigger signal, a reset R terminal of the first RS flip-flop receiving a clock signal;
an S terminal of a second RS flip-flop receiving the clock signal, an R terminal of the second RS flip-flop being connected to a Q terminal of the first RS flip-flop, a Q terminal of the second RS flip-flop being an output terminal of the shift register unit.

2. The shift register unit according to claim 1, wherein each RS flip-flop comprises three NOR gates, and wherein
one input terminal of a first NOR gate is an R terminal of the RS flip-flop, another input terminal of the first NOR gate is connected to an output terminal of a second NOR gate, and an output terminal of the first NOR gate is a Q terminal of the RS flip-flop; and
one input terminal of the second NOR gate is connected to the output terminal of the first NOR gate, another input terminal of the second NOR gate is connected to an output terminal of a third NOR gate, and the output terminal of the second NOR gate is a
Q̅
terminal of the RS flip-flop; and
one input terminal of the third NOR gate is the R terminal of the RS flip-flop, and another input terminal of the third NOR gate is an S terminal of the RS flip-flop.

3. The shift register unit according to claim 2, wherein at least one NOR gate in an RS flip-flop comprises two p-type transistors and two n-type transistors, and wherein
a gate of a first p-type transistor is one input terminal of a NOR gate, a first terminal of the first p-type transistor receives a first voltage signal, and a second terminal of the first p-type transistor is connected to a first terminal of a second p-type transistor;
a gate of the second p-type transistor is another input terminal of the NOR gate, and a second terminal of the second p-type transistor is an output terminal of the NOR gate;
a gate of a first n-type transistor is connected to the gate of the second p-type transistor, a first terminal of the first n-type transistor is the output terminal of the NOR gate, and a second terminal of the first n-type transistor receives a second voltage signal;
a gate of a second n-type transistor is connected to the gate of the first p-type transistor, a first terminal of the second n-type transistor is the output terminal of the NOR gate, and a second terminal of the second n-type transistor receives the second voltage signal;
a substrate of the first p-type transistor is connected to a substrate of the second p-type transistor and receives the first voltage signal;
a substrate of the first n-type transistor is connected to a substrate of the second n-type transistor and receives the second voltage signal; and
a voltage level of the first voltage signal is higher than a voltage level of the second voltage signal.

4. The shift register unit according to claim 2, wherein at least one NOR gate in an RS flip-flop comprises three n-type transistors, and wherein
a gate of a first n-type transistor is one input terminal of a NOR gate, a first terminal of the first n-type transistor is an output terminal of the NOR gate, and a second terminal of the first n-type transistor and a substrate of the first n-type transistor both receive a second voltage signal;
a gate of a second n-type transistor is another input terminal of the NOR gate, a first terminal of the second n-type transistor is the output terminal of the NOR gate, and a second terminal of the second n-type transistor and a substrate of the second n-type transistor both receive the second voltage signal;
a gate of a third n-type transistor and a first terminal of the third n-type transistor both receive a first voltage signal, and a second terminal of the third n-type transistor is connected to a substrate of the third n-type transistor and is the output terminal of the NOR gate; and
a voltage level of the first voltage signal is higher than a voltage level of the second voltage signal.

5. The shift register unit according to claim 2, wherein at least one NOR gate in an RS flip-flop comprises three p-type transistors, and wherein
a gate of a first p-type transistor is one input terminal of a NOR gate, a first terminal of the first p-type transistor receives a first voltage signal, and a second terminal of the first p-type transistor is connected to a first terminal of a second p-type transistor;
a gate of the second p-type transistor is another input terminal of the NOR gate, and a second terminal of the second p-type transistor is an output terminal of the NOR gate;
a substrate of the first p-type transistor is connected to a substrate of the second p-type transistor and receives the first voltage signal;
a gate of a third p-type transistor is connected to a first terminal of the third p-type transistor and receives a second voltage signal, and a second terminal of the third p-type transistor is connected to a substrate of the third p-type transistor and is the output terminal of the NOR gate; and
a voltage level of the first voltage signal is higher than a voltage level of the second voltage signal.

6. A gate driving circuit, comprising a plurality of shift register units, each shift register unit comprising two reset-set RS flip-flops,
a set S terminal of a first RS flip-flop receiving a trigger signal, a reset R terminal of the first RS flip-flop receiving a clock signal;
an S terminal of a second RS flip-flop receiving the clock signal, an R terminal of the second RS flip-flop being connected to a Q terminal of the first RS flip-flop, a Q terminal of the second RS flip-flop being an output terminal of the shift register unit,
wherein,
a trigger signal received by an S terminal of a first RS flip-flop in a (n+1)-th shift register unit is a signal outputted from a Q terminal of a second RS flip-flop in a n-th shift register unit, n being a positive integer;
when n is an odd number, a clock signal received by the n-th shift register unit is a first clock signal;
when n is an even number, a clock signal received by the n-th shift register unit is a second clock signal,
wherein a frequency of the first clock signal is equal to a frequency of the second clock signal.

7. The circuit according to claim 6, wherein the first clock signal is complementary to the second clock signal.

8. A display device, comprising a gate driving circuit, the gate driving circuit comprising a plurality of shift register units, each shift register unit comprising two reset-set RS flip-flops, a set S terminal of a first RS flip-flop receiving a trigger signal, a reset R terminal of the first RS flip-flop receiving a clock signal; an S terminal of a second RS flip-flop receiving the clock signal, an R terminal of the second RS flip-flop being connected to a Q terminal of the first RS flip-flop, a Q terminal of the second RS flip-flop being an output terminal of the shift register unit,
wherein,
a trigger signal received by an S terminal of a first RS flip-flop in a (n+1)-th shift register unit is a signal outputted from a Q terminal of a second RS flip-flop in a n-th shift register unit, n being a positive integer;
when n is an odd number, a clock signal received by the n-th shift register unit is a first clock signal;
when n is an even number, a clock signal received by the n-th shift register unit is a second clock signal,
wherein a frequency of the first clock signal is equal to a frequency of the second clock signal.

9. The circuit according to claim 6, wherein each RS flip-flop comprises three NOR gates, and wherein
one input terminal of a first NOR gate is an R terminal of the RS flip-flop, another input terminal of the first NOR gate is connected to an output terminal of a second NOR gate, and an output terminal of the first NOR gate is a Q terminal of the RS flip-flop; and
one input terminal of the second NOR gate is connected to the output terminal of the first NOR gate, another input terminal of the second NOR gate is connected to an output terminal of a third NOR gate, and the output terminal of the second NOR gate is a terminal of the RS flip-flop; and
one input terminal of the third NOR gate is the R terminal of the RS flip-flop, and another input terminal of the third NOR gate is an S terminal of the RS flip-flop.

10. The circuit according to claim 9, wherein at least one NOR gate in an RS flip-flop comprises two p-type transistors and two n-type transistors, and wherein
a gate of a first p-type transistor is one input terminal of a NOR gate, a first terminal of the first p-type transistor receives a first voltage signal, and a second terminal of the first p-type transistor is connected to a first terminal of a second p-type transistor;
a gate of the second p-type transistor is another input terminal of the NOR gate, and a second terminal of the second p-type transistor is an output terminal of the NOR gate;
a gate of a first n-type transistor is connected to the gate of the second p-type transistor, a first terminal of the first n-type transistor is the output terminal of the NOR gate, and a second terminal of the first n-type transistor receives a second voltage signal;
a gate of a second n-type transistor is connected to the gate of the first p-type transistor, a first terminal of the second n-type transistor is the output terminal of the NOR gate, and a second terminal of the second n-type transistor receives the second voltage signal;
a substrate of the first p-type transistor is connected to a substrate of the second p-type transistor and receives the first voltage signal;
a substrate of the first n-type transistor is connected to a substrate of the second n-type transistor and receives the second voltage signal; and
a voltage level of the first voltage signal is higher than a voltage level of the second voltage signal.

11. The circuit according to claim 9, wherein at least one NOR gate in an RS flip-flop comprises three n-type transistors, and wherein
a gate of a first n-type transistor is one input terminal of a NOR gate, a first terminal of the first n-type transistor is an output terminal of the NOR gate, and a second terminal of the first n-type transistor and a substrate of the first n-type transistor both receive a second voltage signal;
a gate of a second n-type transistor is another input terminal of the NOR gate, a first terminal of the second n-type transistor is the output terminal of the NOR gate, and a second terminal of the second n-type transistor and a substrate of the second n-type transistor both receive the second voltage signal;
a gate of a third n-type transistor and a first terminal of the third n-type transistor both receive a first voltage signal, and a second terminal of the third n-type transistor is connected to a substrate of the third n-type transistor and is the output terminal of the NOR gate; and
a voltage level of the first voltage signal is higher than a voltage level of the second voltage signal.

12. The circuit according to claim 9, wherein at least one NOR gate in an RS flip-flop comprises three p-type transistors, and wherein
a gate of a first p-type transistor is one input terminal of a NOR gate, a first terminal of the first p-type transistor receives a first voltage signal, and a second terminal of the first p-type transistor is connected to a first terminal of a second p-type transistor;
a gate of the second p-type transistor is another input terminal of the NOR gate, and a second terminal of the second p-type transistor is an output terminal of the NOR gate;
a substrate of the first p-type transistor is connected to a substrate of the second p-type transistor and receives the first voltage signal;
a gate of a third p-type transistor is connected to a first terminal of the third p-type transistor and receives a second voltage signal, and a second terminal of the third p-type transistor is connected to a substrate of the third p-type transistor and is the output terminal of the NOR gate; and
a voltage level of the first voltage signal is higher than a voltage level of the second voltage signal.

13. The display device according to claim 8, wherein each RS flip-flop comprises three NOR gates, and wherein
one input terminal of a first NOR gate is an R terminal of the RS flip-flop, another input terminal of the first NOR gate is connected to an output terminal of a second NOR gate, and an output terminal of the first NOR gate is a Q terminal of the RS flip-flop; and
one input terminal of the second NOR gate is connected to the output terminal of the first NOR gate, another input terminal of the second NOR gate is connected to an output terminal of a third NOR gate, and the output terminal of the second NOR gate is a terminal of the RS flip-flop; and
one input terminal of the third NOR gate is the R terminal of the RS flip-flop, and another input terminal of the third NOR gate is an S terminal of the RS flip-flop.

14. The display device according to claim 13, wherein at least one NOR gate in an RS flip-flop comprises two p-type transistors and two n-type transistors, and wherein
a gate of a first p-type transistor is one input terminal of a NOR gate, a first terminal of the first p-type transistor receives a first voltage signal, and a second terminal of the first p-type transistor is connected to a first terminal of a second p-type transistor;
a gate of the second p-type transistor is another input terminal of the NOR gate, and a second terminal of the second p-type transistor is an output terminal of the NOR gate;
a gate of a first n-type transistor is connected to the gate of the second p-type transistor, a first terminal of the first n-type transistor is the output terminal of the NOR gate, and a second terminal of the first n-type transistor receives a second voltage signal;
a gate of a second n-type transistor is connected to the gate of the first p-type transistor, a first terminal of the second n-type transistor is the output terminal of the NOR gate, and a second terminal of the second n-type transistor receives the second voltage signal;
a substrate of the first p-type transistor is connected to a substrate of the second p-type transistor and receives the first voltage signal;
a substrate of the first n-type transistor is connected to a substrate of the second n-type transistor and receives the second voltage signal; and
a voltage level of the first voltage signal is higher than a voltage level of the second voltage signal.

15. The display device according to claim 13, wherein at least one NOR gate in an RS flip-flop comprises three n-type transistors, and wherein
a gate of a first n-type transistor is one input terminal of a NOR gate, a first terminal of the first n-type transistor is an output terminal of the NOR gate, and a second terminal of the first n-type transistor and a substrate of the first n-type transistor both receive a second voltage signal;
a gate of a second n-type transistor is another input terminal of the NOR gate, a first terminal of the second n-type transistor is the output terminal of the NOR gate, and a second terminal of the second n-type transistor and a substrate of the second n-type transistor both receive the second voltage signal;
a gate of a third n-type transistor and a first terminal of the third n-type transistor both receive a first voltage signal, and a second terminal of the third n-type transistor is connected to a substrate of the third n-type transistor and is the output terminal of the NOR gate; and
a voltage level of the first voltage signal is higher than a voltage level of the second voltage signal.

16. The display device according to claim 13, wherein at least one NOR gate in an RS flip-flop comprises three p-type transistors, and wherein
a gate of a first p-type transistor is one input terminal of a NOR gate, a first terminal of the first p-type transistor receives a first voltage signal, and a second terminal of the first p-type transistor is connected to a first terminal of a second p-type transistor;
a gate of the second p-type transistor is another input terminal of the NOR gate, and a second terminal of the second p-type transistor is an output terminal of the NOR gate;
a substrate of the first p-type transistor is connected to a substrate of the second p-type transistor and receives the first voltage signal;
a gate of a third p-type transistor is connected to a first terminal of the third p-type transistor and receives a second voltage signal, and a second terminal of the third p-type transistor is connected to a substrate of the third p-type transistor and is the output terminal of the NOR gate; and
a voltage level of the first voltage signal is higher than a voltage level of the second voltage signal.

17. The display device according to claim 8, wherein the first clock signal is complementary to the second clock signal.
